(19) United States
(12) Patent Application Publication
(10) Pub. No.: US 2023/0402508 A1
(43) Pub. Date: Dec. 14, 2023

(54) Epitaxial Structures In Semiconductor Devices

(71) Applicant: Taiwan Semiconductor Manufacturing Co., Ltd., Hsinchu (TW)

(72) Inventors: Cheng-Wei CHANG, Taipei City (TW); Shahaji B. MORE, Hsinchu City (TW); Lun-Kuang TAN, Hsinchu City (TW); Chi-Yu CHOU, Hsinchu City (TW); Yueh-Ching PAI, Taichung City (TW)

(73) Assignee: Taiwan Semiconductor Manufacturing Co., Ltd., Hsinchu (TW)

(21) Appl. No.: 18/128,061

(22) Filed: Mar. 29, 2023

Related U.S. Application Data
(60) Provisional application No. 63/381,321, filed on Oct. 28, 2022.
(60) Provisional application No. 63/351,183, filed on Jun. 10, 2022.

(51) Int. Cl. H01L 29/06; H01L 27/092; H01L 29/423; H01L 29/775; H01L 29/66; H01L 29/786; H01L 21/8238

(52) U.S. Cl. CPC H01L 29/0673; H01L 27/092; H01L 29/42392; H01L 29/775; H01L 29/66439; H01L 29/78696; H01L 21/823807; H01L 21/823814

(57) ABSTRACT

A semiconductor device and a method of fabricating the semiconductor device are disclosed. The semiconductor device includes a substrate, a fin base disposed on the substrate, a stack of nanostructured channel regions disposed on a first portion of the fin base, a gate structure surrounding the nanostructured channel regions, a source/drain (S/D) region disposed on a second portion of the fin base, an air spacer disposed between the S/D region and the fin base, and a dielectric layer disposed between the air spacer and the fin base.

### CROSS-REFERENCE TO RELATED APPLICATIONS

This application claims the benefit of U.S. Provisional Patent Application No. 63/381,321, titled “Epitaxial Structures in Semiconductor Devices,” filed Oct. 28, 2022, and U.S. Provisional Patent Application No. 63/351,183, titled “Epitaxial Structures in Semiconductor Devices,” filed Jun. 10, 2022, each of which is incorporated by reference in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), fin field effect transistors (finFETs), and gate-all-around (GAA) FETs. Such scaling down has increased the complexity of semiconductor manufacturing processes.

### BRIEF DESCRIPTION OF THE DRAWINGS

Aspects of this disclosure are best understood from the following detailed description when read with the accompanying figures.

FIG. 1A illustrates an isometric view of a semiconductor device, in accordance with some embodiments.

FIG. 1B illustrates a cross-sectional view of a semiconductor device with air spacers under epitaxial source/drain (S/D) regions, in accordance with some embodiments.

FIG. 1C illustrates a cross-sectional view of a semiconductor device with front-side and back-side contact structures on epitaxial S/D regions, in accordance with some embodiments.

FIG. 2 is a flow diagram of a method for fabricating a semiconductor device, in accordance with some embodiments.

FIGS. 3-15 illustrate cross-sectional views of a semiconductor device at various stages of its fabrication process, in accordance with some embodiments.

FIGS. 16A-19B illustrate cross-sectional views of a semiconductor device with n- and p-type FETs at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. The terms “about” and “substantially” can refer to a percentage of the values as interpreted by those skilled in relevant art(s) in light of the teachings herein.

The fin structures disclosed herein may be patterned by any suitable method. For example, the fin structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures.

GAA FETs can include fin bases disposed on a substrate, stacks of nanostructured channel regions disposed on the fin bases, gate structures surrounding each of the nanostructured channel regions, and inner spacers on sidewalls of the gate structures. The GAA FETs can further include S/D regions, each of which can be disposed between a pair of nanostructured channel regions and on a fin portion between the pair of nanostructured channel regions. Each of the S/D regions can be formed by the merging of an epitaxial portion grown on the fin portion with epitaxial portions grown on sidewalls of the pair of nanostructured channel regions. The direction and/or location of the merging of the epitaxial portions can be challenging to control, which can lead to the formation of voids in the S/D regions. Also, due to the growth of the epitaxial portions on different surfaces, any lattice mismatch between the epitaxial portions can induce crystal defects, such as dislocations in the S/D regions. The presence of such voids and/or crystal defects in the S/D regions can degrade the performance of the GAA FETs.

To address the abovementioned challenges of forming epitaxial S/D regions in GAA FETs, the present disclosure provides examples methods of forming epitaxial S/D regions on nanostructured channel regions that can prevent or mitigate the formation of voids and/or crystal defects in the S/D regions. In some embodiments, air spacers and dielectric layers can be formed between S/D regions and fin bases to limit the epitaxial growth of the S/D regions to the sidewalls of the nanostructured channel regions and to prevent any epitaxial growth of the S/D regions on the fin bases. As a result, the merging of different epitaxial portions grown on different surfaces can be prevented, which can prevent or mitigate the formation of voids and/or crystal defects in the S/D regions.

In some embodiments, portions of the fin bases under the dielectric layers can be replaced with back-side contact structures and the dielectric layers can be etched to form anchor structures to prevent the metal of the back-side contact structures from being pulled out during a planarization operation. The back-side contact structures can be electrically connected to a back-side power rail formed in a back-side dielectric layer disposed on a back-side of the substrate. In some embodiments, the formation of the back-side power rail and the electrical connections of one or more of the S/D regions to the back-side power rail can reduce device area and the number and dimension of interconnects between S/D regions and power rails, thus reducing device power consumption compared to other semiconductor devices without back-side power rails.

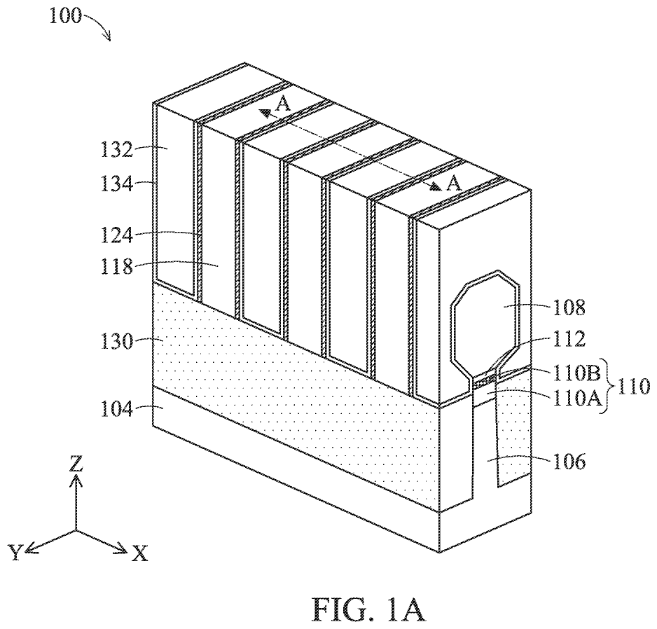

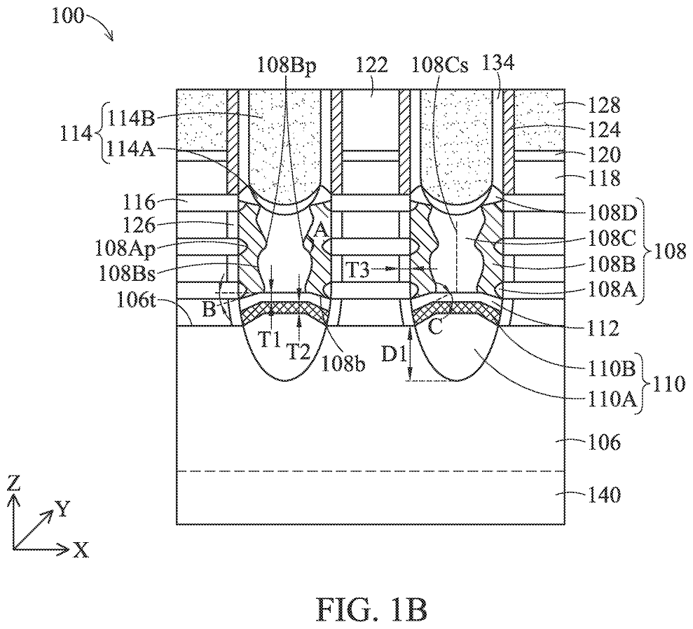

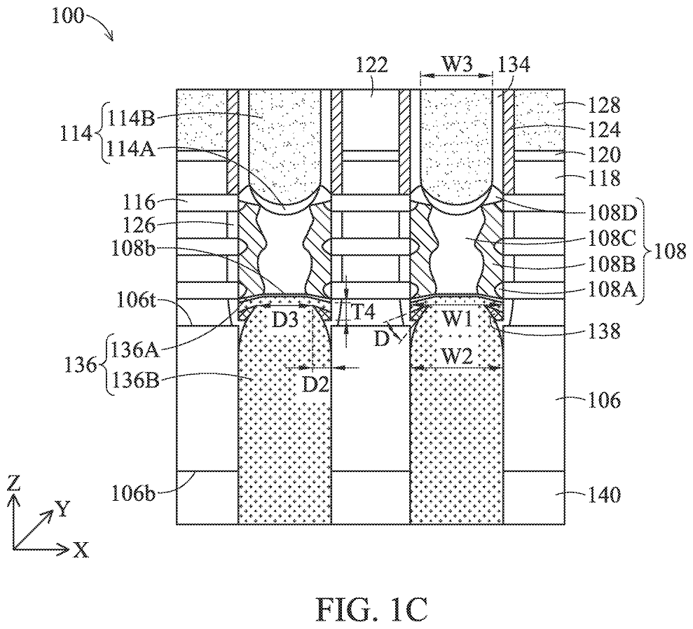

FIG. 1A illustrates an isometric view of a FET 100 (also referred to as a “GAA FET 100”), according to some embodiments. FIG. 1B illustrates a cross-sectional view of FET 100, along line A-A of FIG. 1A, according to some embodiments. FIG. 1C illustrates a different cross-sectional view of FET 100, along line A-A of FIG. 1A, according to some embodiments. FIGS. 1B and 1C illustrate cross-sectional views of FET 100 with additional structures that are not shown in FIG. 1A for simplicity. The discussion of elements with the same annotations applies to each other, unless mentioned otherwise. In some embodiments, FET 100 can represent n-type FET 100 (NFET 100) or p-type FET 100 (PFET 100) and the discussion of FET 100 applies to both NFET 100 and PFET 100, unless mentioned otherwise. In some embodiments, NFET 100 and PFET 100 can be formed on the same substrate.

Referring to FIGS. 1A and 1B, in some embodiments, FET 100 can include (i) a substrate 104, (ii) a fin base 106, (iii) S/D regions 108, (iv) epitaxial growth inhibition (EGI) layers 110, (v) air spacers 112, (vi) S/D contact structures 114, (vii) nanostructured channel regions 116, (viii) gate structures 118, (ix) conductive capping layers 120, (x) insulating capping layers 122, (xi) outer gate spacers 124, (xii) inner gate spacers 126, (xiii) gate contact structures 128, (xiv) shallow trench isolation (STI) regions 130, (xv) interlayer dielectric (ILD) layers 132, and (xvi) etch stop layers (ESLs) 134.

In some embodiments, substrate 104 can be a semiconductor material, such as silicon, germanium (Ge), silicon germanium (SiGe), a silicon-on-insulator (SOI) structure, and a combination thereof. Further, substrate 104 can be doped with p-type dopants (e.g., boron, indium, aluminum, or gallium) or n-type dopants (e.g., phosphorus or arsenic). In some embodiments, other FETs similar to FET 100 can be formed on substrate 104. In some embodiments, PFET 100 and NFET 100 can be formed on different regions of substrate 104. In some embodiments, PFET 100 and NFET 100 can be formed adjacent to each other and can have common elements, such as gate structures, gate spacers, ILD layers, ESLs, and STI regions.

In some embodiments, fin base 106 can be formed by patterning and etching substrate 104. Thus, fin base 106 can include materials similar to that of substrate 104. In some embodiments, fin base 106 of PFET 100 can include n-type dopants (e.g., phosphorus or arsenic) and fin base 106 of NFET 100 can include p-type dopants (e.g., boron, indium, aluminum, or gallium).

In some embodiments, each S/D region 108 can be disposed above fin base 106 and can be electrically isolated from fin base 106 by EGI layers 110 and air spacers 112. In some embodiments, each S/D region 108 can include S/D sub-regions 108A, 108B, 108C, and 108D. S/D sub-regions 108A can be disposed directly on and can be epitaxially grown on sidewalls of nanostructured channel regions 116. In some embodiments, S/D sub-regions 108A can have a triangular-shaped cross-sectional profile. The number of S/D sub-regions 108A in each S/D region 108 can be equal to the number of nanostructured channel regions 116 facing each S/D region 108. For example, as shown in FIG. 1B, each S/D region 108 includes six S/D sub-regions 108A, which is equal to the six nanostructured channel regions 116 facing each S/D region 108.

Each S/D region 108 can include a pair of S/D sub-regions 108B facing each other. First portions of S/D sub-regions 108B can be disposed directly on and can be epitaxially grown on S/D sub-regions 108A. Second portions of S/D sub-regions 108B can be disposed directly on sidewalls of inner gate spacers 126 and between adjacent S/D sub-regions 108A. The second portions of S/D sub-regions 108B can be formed by the merging of adjacent first portions of S/D sub-regions 108B. In some embodiments, an air gap (not shown) can be present between the sidewalls of inner gate spacers 126 and the second portion of S/D sub-regions 108B. In some embodiments, sidewalls 108Bs of S/D sub-regions 108B can have a zigzag-shaped cross-sectional profile. In some embodiments, peak regions 108Bp of S/D sub-regions 108B can be substantially aligned to peaks regions 108Ap of S/D sub-regions 108A. In some embodiments, peak regions 108Bp can have vertex angles A of about 100 degrees to about 175 degrees.

In some embodiments, S/D sub-region 108C can fill the space between the pair of S/D sub-regions 108B in each S/D region 108. S/D sub-regions 108C can be disposed directly on and can be epitaxially grown on the pair of S/D sub-regions 108B. In some embodiments, each S/D sub-region 108C can have a seam 108Cs, where portions of S/D sub-region 108C epitaxially grown on the pair of S/D sub-regions 108B are merged. The epitaxial growth of S/D sub-regions 108B and 108C can be controlled to prevent these S/D sub-regions from extending to inner gate spacers 126 that are disposed directly on fin base 106. That is, S/D sub-regions 108B and 108C are not in contact with inner gate spacers 126 that are disposed directly on fin base 106. In some embodiments, back-sides of S/D sub-regions 108C can have substantially linear cross-sectional profiles along X- and Y-axes and back-sides (e.g., sides facing substrate 104) of S/D sub-regions 108B can have sloped cross-sectional profiles that form an angle B of about 3 degrees to about degrees with back-sides of S/D sub-regions 108C.

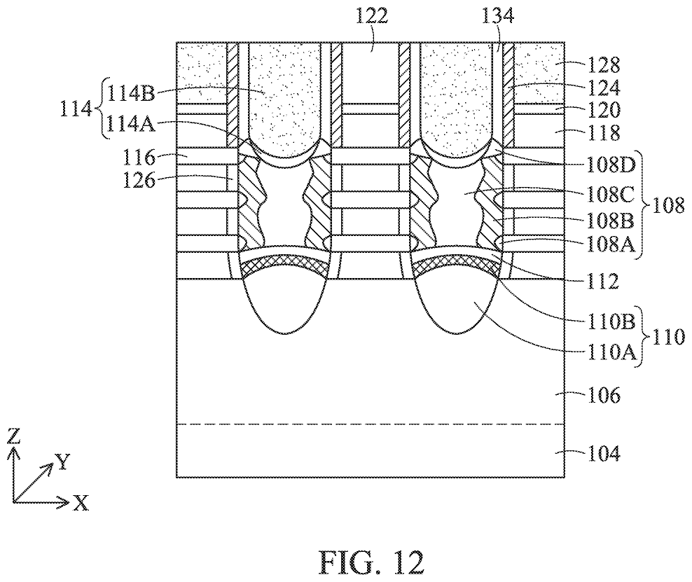

In some embodiments, S/D sub-regions 108D can be disposed directly on S/D sub-regions 108A and 108B and not on S/D sub-regions 108C in areas of S/D regions 108 occupied by S/D contact structures 114, as shown in FIG. 1B. In some embodiments, S/D sub-regions 108D can be disposed directly on S/D sub-regions 108A, 108B, and 108C in areas of S/D regions 108 unoccupied by S/D contact structures 114, as shown in FIG. 12. S/D sub-regions 108D can act as a capping layer to protect S/D sub-regions 108A, 108B, and 108C, and to prevent out-diffusion of dopants from S/D sub-regions 108B and 108C during any subsequent processing of FET 100.

In some embodiments, for NFET 100, S/D sub-regions 108A, 108B, 108C, and 108D can include epitaxially-grown Si without any Ge atoms and can differ from each other based on n-type dopant (e.g., phosphorus atoms) concentrations. For example, S/D sub-regions 108C can have an n-type dopant concentration higher than that in S/D sub-regions 108A, 108B, and 108D. A higher dopant concentration in S/D sub-regions 108C can reduce contact resistance between S/D regions 108 and S/D contact structures 114. In some embodiments, S/D sub-regions 108A can be undoped. In some embodiments, S/D sub-regions 108B can include an arsenic dopant concentration of about 1×10²⁰ atoms/cm³ to about 1×10²¹ atoms/cm³. In some embodiments, S/D sub-regions 108C can include a phosphorus dopant concentration of about 1×10²¹ atoms/cm³ to about 4×10²¹ atoms/cm³. In some embodiments, S/D sub-regions 108D can include a phosphorus dopant concentration of about 1×10²¹ atoms/cm³ to about 2×10²¹ atoms/cm³.

In some embodiments, for PFET 100, S/D sub-regions 108A can include epitaxially-grown Si without any Ge atoms and S/D sub-regions 108B, 108C, and 108D can include epitaxially-grown SiGe. S/D sub-regions 108B, 108C, and 108D can differ from each other based on a relative concentration of Ge atoms with respect to Si atoms. For example, the Ge atom concentration in S/D sub-regions 108C can be higher than that in S/D sub-regions 108B and 108D. In some embodiments, S/D sub-regions 108B can include a Ge atom concentration of about 25 atomic % to about 45 atomic % with any remaining atomic % being Si atoms. In some embodiments, S/D sub-regions 108C can include a Ge atom concentration of about 45 atomic % to about 60 atomic % with any remaining atomic % being Si atoms. In some embodiments, S/D sub-regions 108D can include a Ge atom concentration of about 45 atomic % to about 55 atomic % with any remaining atomic % being Si atoms.

In some embodiments, for PFET 100, S/D sub-regions 108A, 108B, 108C, and 108D can differ from each other based on p-type dopant (e.g., boron atoms) concentrations. For example, S/D sub-regions 108C can have a p-type dopant concentration higher than that in S/D sub-regions 108A, 108B, and 108D. In some embodiments, S/D sub-regions 108A can be undoped. In some embodiments, S/D sub-regions 108B can include a boron dopant concentration of about 1×10²⁰ atoms/cm³ to about 8×10²⁰ atoms/cm³. In some embodiments, S/D sub-regions 108C can include a boron dopant concentration of about 8×10²⁰ atoms/cm³ to about 3×10²¹ atoms/cm³. In some embodiments, S/D sub-regions 108D can include a boron dopant concentration of about 1×10²¹ atoms/cm³ to about 2×10²¹ atoms/cm³.

In some embodiments, EGI layers 110 can be disposed under S/D regions 108 and in a recessed region of fin base 106. The recessed region in fin base 106 can be formed during the formation of S/D regions 108, as described in detail below. EGI layers 110 can prevent the epitaxial growth of S/D regions 108 on fin base 106 and limit the epitaxial growth of the S/D regions 108 to the sidewalls of nanostructured channel regions 116. As discussed above, preventing the merging of different epitaxial portions grown on fin base 106 and nanostructured channel regions 116 can prevent or mitigate the formation of voids and/or crystal defects in S/D regions 108. EGI layers 110 can also prevent the diffusion of dopants from S/D region 108 to fin base 106, thus preventing short channel effects in FET 100.

In some embodiments, the material of EGI layers 110 inhibits the epitaxial growth of S/D regions 108 on EGI layers 110. As a result, air spacers 112 can be formed between back-sides 108b of S/D regions 108 and EGI layers 110. In some embodiments, air spacers 112 can have a thickness T1 of about 3 nm to about 10 nm. Within this range of thickness T1, air spacers 112 can prevent current leakage between S/D regions 108 and fin base 106 without compromising the size and manufacturing cost of FET 100. In some embodiments, the presence of air spacers 112 between back-sides 108b of S/D regions 108 and EGI layers 110 can eliminate the process of removing layers from back-sides 108b prior to forming back-side S/D contact structures 136, as described below with reference to FIGS. 1C and 15-17. As a result, contamination of S/D regions 108 from etching chemicals can be prevented during the formation of back-side S/D contact structures 136.

In some embodiments, each EGI layer 110 can include a first dielectric layer 110A disposed in the recessed region of fin base 106 and a second dielectric layer 110B disposed on first dielectric layer 110A. In some embodiments, first and second isolation layers 110A and 110B can include dielectric materials similar to or different from each other. In some embodiments, first and second dielectric layers 110A and 110B can include nitride materials, such as silicon nitride (SiₓN_{y}), silicon oxynitride (SiₓO_{y}Nₓ), silicon carbon oxynitride (SiCON), and silicon carbon nitride (SiₓC_{y}N_{z}). In some embodiments, the nitride material of second dielectric layer 110B can have a nitrogen atom concentration higher than that of the nitride material of first dielectric layer 110A. Due to the higher nitrogen atom concentration in second dielectric layer 110B, the dielectric constant and the etch resistance of second dielectric layer 110B can be higher than that of first dielectric layer 110A. The higher etch resistance of second dielectric layers 110B can protect S/D regions 108 during the etching of first dielectric layers 110A, fin base 106, and substrate 104 to form back-side S/D contact structures 136.

In some embodiments, second dielectric layer 110B can have a thickness T2 of about 5 nm to about 15 nm. Within this range of thickness T2, second dielectric layer 110B can adequately protect S/D regions 108 during the formation of back-side S/D contact structures 136 without compromising the dimensions of air spacers 112 and the volume of S/D regions 108. In some embodiments, middle portions of second dielectric layers 110B can have substantially linear cross-sectional profiles along X- and Y-axes and end portions of second dielectric layers 110B can have sloped cross-sectional profiles that form an angle C of about 23 degrees to about 70 degrees with top surfaces of the middle portions. In some embodiments, sidewalls of second dielectric layers 110B can be in direct contact with sidewalls of inner gate spacers 126.

In some embodiments, top surfaces of first and second dielectric layers 110A and 110B can extend above the top surface of fin base 106. In some embodiments, the cross-sectional profiles of the top surfaces of first and second dielectric layers 110A and 110B can be similar to the cross-sectional profiles of back-sides 108b of S/D regions 108. In some embodiments, first dielectric layers 110A extend a distance D1 of about 20 nm to about 40 nm into fin base 106. This distance D1 is equal to the recessed region formed in fin base 106 during the formation of S/D regions 108, as described in detail below. In some embodiments, if distance D1 below 20 nm, first dielectric layers 110A may not adequately prevent the diffusion of dopants from S/D regions 108 to fin base 106. On the other hand, if distance D1 above 40 nm, the processing time (e.g., etching time, deposition time) for forming first dielectric layers 110A increases, and consequently increases the manufacturing cost of FET 100.

In some embodiments, S/D contact structures 114 can be disposed directly on S/D regions 108 to electrically connect S/D regions 108 to other elements of FET 100 and/or to other active and/or passive devices (not shown) in an integrated circuit. In some embodiments, each S/D contact structure 114 can include (i) a silicide layer 114A, and (ii) a contact plug 114B disposed directly on silicide layer 114A. In some embodiments, silicide layers 114A can be disposed directly on S/D sub-regions 108B, 108C, and 108D and may not be in contact with S/D sub-regions 108A. In some embodiments, the surface areas of silicide layers 114A in direct contact with higher doped S/D sub-regions 108C are greater than the surface areas of silicide layers 114A in direct contact with S/D sub-regions 108B and 108D for minimizing contact resistance between S/D regions 108 and S/D contact structures 114.

In some embodiments, silicide layer 114A can include titanium silicide (TiₓSi_{y}), tantalum silicide (TaₓSi_{y}), molybdenum (MoₓSi_{y}), zirconium silicide (ZrₓSi_{y}), hafnium silicide (HfₓSi_{y}), scandium silicide (ScₓSi_{y}), yttrium silicide (YₓSi_{y}), terbium silicide (TbₓSi_{y}), lutetium silicide (LuₓSi_{y}), erbium silicide (ErₓSi_{y}), ybtterbium silicide (YbₓSi_{y}), europium silicide (EuₓSi_{y}), thorium silicide (ThₓSi_{y}), other suitable metal silicide materials, or a combination thereof for NFET 100. In some embodiments, silicide layer 114A can include nickel silicide (NiₓSi_{y}), cobalt silicide (CoₓSi_{y}), manganese silicide (MnₓSi_{y}), tungsten silicide (WₓSi_{y}), iron silicide (FeₓSi_{y}), rhodium silicide (RhₓSi_{y}), palladium silicide (PdₓSi_{y}), ruthenium silicide (RuₓSi_{y}), platinum silicide (PtₓSi_{y}), iridium silicide (IrₓSi_{y}), osmium silicide (OsₓSi_{y}), other suitable metal silicide materials, or a combination thereof for PFET 100. In some embodiments, contact plugs 114B can include conductive materials, such as cobalt (Co), tungsten (W), ruthenium (Ru), iridium (Ir), nickel (Ni), osmium (Os), rhodium (Rh), aluminum (Al), molybdenum (Mo), copper (Cu), zirconium (Zr), stannum (Sn), silver (Ag), gold (Au), zinc (Zn), cadmium (Cd), and a combination thereof.

In some embodiments, STI regions 130, ILD layers 132, and ESLs 134 can include dielectric materials, such as silicon oxide (SiO₂), silicon nitride (SiN), silicon oxynitride (SiON), silicon oxycarbide (SiCO), silicon carbon nitride (SiCN), silicon carbon oxynitride (SiCON), and other suitable dielectric materials. In some embodiments, ILD layers 132 can include an oxide material and ESLs 134 can include a nitride material different from ILD layers 132.

In some embodiments, nanostructured channel regions 116 can include semiconductor materials, such as Si, silicon arsenide (SiAs), silicon phosphide (SiP), SiC, SiCP, SiGe, Silicon Germanium Boron (SiGeB), Germanium Boron (GeB), Silicon-Germanium-Tin-Boron (SiGeSnB), a III-V semiconductor compound, or other suitable semiconductor materials. Though rectangular cross-sections of nanostructured channel regions 116 are shown, nanostructured channel regions 116 can have cross-sections of other geometric shapes (e.g., circular, elliptical, triangular, or polygonal). In some embodiments, nanostructured channel regions 116 can have be in the form of nanosheets, nanowires, nanorods, nanotubes, or other suitable nanostructured shapes. As used herein, the term “nanostructured” defines a structure, layer, and/or region as having a horizontal dimension (e.g., along an X- and/or Y-axis) and/or a vertical dimension (e.g., along a Z-axis) less than about 100 nm, for example about 90 nm, about 50 nm, about 10 nm, or other values less than about 100 nm.

In some embodiments, gate structures 118 can be multi-layered structures and can surround each nanostructured channel region 116 for which gate structures 118 can be referred to as “GAA structures.” The different layers of gate structures 118 are not shown for simplicity. In some embodiments, each gate structure 118 can include (i) an interfacial oxide (IL) layer disposed on nanostructured channel regions 116, (ii) a high-k gate dielectric layer disposed on the IL layer, and (iii) a conductive layer disposed on the high-k gate dielectric layer. In some embodiments, the IL layer can include SiO₂, silicon germanium oxide (SiGeOₓ), or germanium oxide (GeOₓ). In some embodiments, the high-k gate dielectric layer can include a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), zirconium aluminum oxide (ZrAlO), zirconium silicate (ZrSiO₂), lanthanum oxide (La₂O₃), aluminum oxide (Al₂O₃) zinc oxide (ZnO), hafnium zinc oxide (HfZnO), and yttrium oxide (Y₂O₃).

In some embodiments, the conductive layer can be a multi-layered structure. The different layers of the conductive layer are not shown for simplicity. Each conductive layer can include a work function metal (WFM) layer disposed on the high-k gate dielectric layer and a gate metal fill layer disposed on the WFM layer. In some embodiments, the WFM layer can include titanium aluminum (TiAl), titanium aluminum carbide (TiAlC), tantalum aluminum (TaAl), tantalum aluminum carbide (TaAlC), Al-doped Ti, Al-doped TiN, Al-doped Ta, Al-doped TaN, or other suitable Al-based materials for NFET 100. In some embodiments, the WFM layer can include substantially Al-free (e.g., with no Al) Ti-based or Ta-based nitrides or alloys, such as titanium nitride (TiN), titanium silicon nitride (TiSiN), titanium gold (Ti—Au) alloy, titanium copper (Ti—Cu) alloy, tantalum nitride (TaN), tantalum silicon nitride (TaSiN), tantalum gold (Ta—Au) alloy, and tantalum copper (Ta—Cu) for PFET 100. The gate metal fill layers can include a suitable conductive material, such as tungsten (W), Ti, silver (Ag), ruthenium (Ru), molybdenum (Mo), copper (Cu), cobalt (Co), Al, iridium (Ir), nickel (Ni), metal alloys, and a combination thereof.

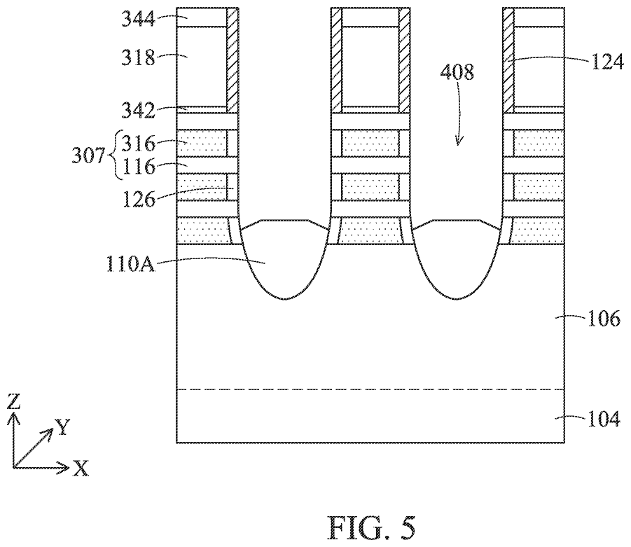

In some embodiments, gate structure 118 can be electrically isolated from adjacent S/D contact structures 114 by outer gate spacers 124 and the portions of gate structures 118 surrounding nanostructured channel regions 116 can be electrically isolated from adjacent S/D regions 108 by inner gate spacers 126. Outer gate spacers 124 and inner gate spacers 126 can include a material similar to or different from each other. In some embodiments, outer gate spacers 124 and inner gate spacers 126 can include an insulating material, such as SiO₂, SiN, SiON, SiCO, SiCN, SiCON, and other suitable insulating materials. In some embodiments, each inner gate spacer 126 can have a thickness T3 of about 1 nm to about 10 nm. Within this range of thickness T3, adequate electrical isolation can be provided by inner gate spacers 126 between gate structures 108 and adjacent S/D regions 108 without compromising the size and manufacturing cost of FET 100. In some embodiments, inner gate spacers 126 and first dielectric layers 110A are formed from portions of the same material layer for the ease of fabrication, as described below with reference to FIG. 5.

Conductive capping layers 120 can be disposed directly on gate structures 118. Conductive capping layers 120 can provide conductive interfaces between gate structures 118 and gate contact structures 128 to electrically connect gate structures 118 to gate contact structures 128 without forming gate contact structures 128 directly on or within gate structures 118. Gate contact structure 128 is not formed directly on or within gate structures 118 to prevent contamination by any of the processing materials used in the formation of gate contact structures 128. Contamination of gate structures 118 can lead to the degradation of device performance. Thus, with the use of conductive capping layers 120, gate structures 118 can be electrically connected to gate contact structures 128 without compromising the integrity of gate structures 118. In some embodiments, conductive capping layer 120 can have a thickness of about 1 nm to about 8 nm for adequately providing a conductive interface between gate structures 118 and gate contact structures 128 without compromising the size and manufacturing cost of FET 100. In some embodiments, conductive capping layers 120 can include a metallic material, such as W, Ru, Mo, Co, other suitable metallic materials, and a combination thereof.

Insulating capping layers 122 can be disposed directly on conductive capping layers 120. Insulating capping layers 122 can protect the underlying conductive capping layers 120 from structural and/or compositional degradation during subsequent processing of FET 100. In some embodiments, insulating capping layers 122 can include a dielectric nitride or carbide material, such as SiₓN_{y}, SiON, SiCN, SiC, SiCON, and other suitable dielectric nitride or carbide materials. In some embodiments, insulating capping layers 122 can have a thickness of about 5 nm to about 10 nm for adequate protection of the underlying conductive capping layers 120 without compromising the size and manufacturing cost of FET 100. In some embodiments, top surfaces of insulating capping layers 122 can be substantially coplanar with top surfaces of ILD layers 132.

Gate contact structures 128 can be disposed in insulating capping layers 122 and can be disposed directly on conductive capping layers 120. In some embodiments, top surfaces of gate contact structures 128 can be substantially coplanar with top surfaces of ILD layers 132. In some embodiments, gate contact structures 128 can include a metallic material, such as W, Ru, Mo, Co, other suitable metallic materials, and a combination thereof. In some embodiments, conductive capping layers 120, contact plugs 114B, and gate contact structures 128 can have a metallic material similar to or different from each other.

FIG. 1C illustrates another cross-sectional view of FET 100 along line A-A of FIG. 1A when FET 100 includes back-side elements, such as back-side S/D contact structures 136, anchor structures 138, and back-side dielectric layers 140 in addition to the elements discussed in FIG. 1B.

In some embodiments, back-side S/D contact structures 136 can be disposed directly on back-sides 108b of S/D regions 108 and in fin base 106. Back-side S/D contact structures 136 can electrically connect S/D regions 108 to a back-side power rail (not shown) disposed on back-side S/D contact structures 136. The back-side power rail can include metal lines (not shown) for providing power supply to S/D regions 108 through back-side S/D contact structures 136. With the use of back-side power rail, device area for placing interconnects between S/D regions 108 and power supplies can be reduced, thus reducing power consumption compared to other FETs without back-side power rails.

In some embodiments, each back-side S/D contact structure 136 can include (i) a silicide layer 136A disposed directly on back-sides 108b of S/D regions 108 and (ii) a contact plug 136B disposed directly on silicide layer 136A. The discussion of silicide layer 114A and contact plug 114B applies to silicide layer 136A and contact plugs 136B, respectively, unless mentioned otherwise. In some embodiments, each silicide layer 136A can have a thickness of about 3 nm to about 50 nm to minimize contact resistance between contact plugs 136B and S/D regions 108.

In some embodiments, first and second dielectric layers 110A and 110B of EGI layers 110 can be partially removed to form a pair of anchor structures 138 in each contact plug 136B during the formation of back-side S/D contact structures 136. Anchor structures 138 can be disposed in contact plugs 136B to prevent the metal of contact plugs 136B from being “pulled-out” during a planarization operation performed on contact plugs 136B. In some embodiments, anchor structures 138 can have triangular-shaped cross-sectional profiles. The first and second sides of anchor structures 138 can be disposed in contact plugs 136B and the third sides of anchor structures 138 can be disposed on sidewalls of fin base 106 and inner gate spacers 126 that are facing contact plugs 136B. The first and second sides of each anchor structure 138 can form a vertex angle D of about 20 degrees to about 70 degrees in contact plug 136B. In some embodiments, each anchor structure 138 extends a lateral distance D2 of about 2 nm to about 15 nm from the sidewall of fin base 106 on which it is disposed to contact plug 136B. In some embodiments, the pair of anchor structures 138 in each contact plug 136B can be separated from each other by a distance D3 of about 15 nm to about 45 nm to prevent the metal of contact plugs 136B from being “pulled-out” during the planarization operation. In some embodiments, distance D3 is greater than distance D2.

In some embodiments, each contact plug 136B can have a first contact portion between anchor structures 138 and S/D regions 108 and sidewalls of the first contact portion can be in contact with sidewalls of inner gate spacers 126 that are adjacent to the contact portion. In some embodiments, the first contact portion can have a thickness T4 of about 3 nm to about 13 nm and a width W1 of about 13 nm to about 60 nm. In some embodiments, each contact plug 136B can have a second contact portion disposed in fin base 106. The second contact portion can have a width W2 of about 10 nm to about 50 nm, which is smaller than width W1 and greater than a width W3 of each contact plug 114B.

In some embodiments, back-side dielectric layers 140 can include a nitride material (e.g., SiN) and can be disposed directly on back-side 106b of fin base 106. Back-side dielectric layers 140 can function as a passivation layer and protect fin base 106 during the formation of back-side elements, such as back-side S/D contact structures 136 and back-side power rail (not shown). In addition, back-side dielectric layers 140 can provide electrical isolation between back-side S/D contact structures 136.

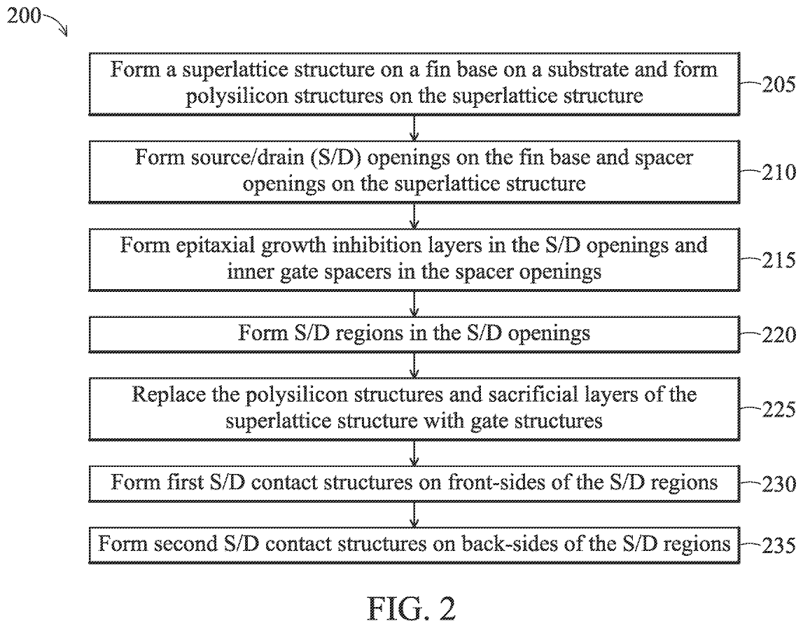

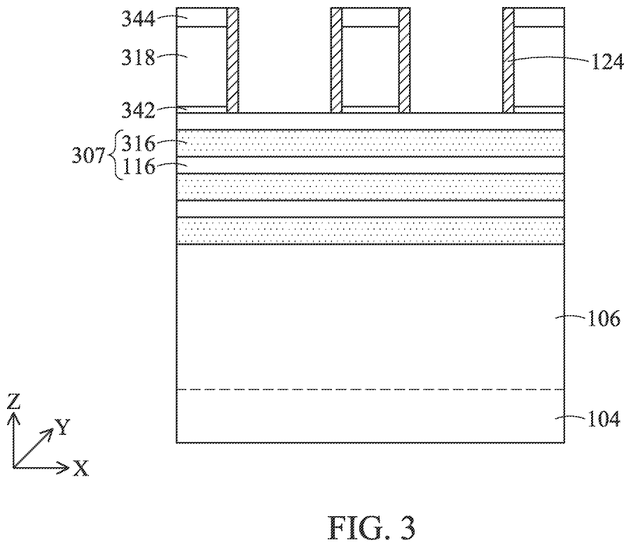

FIG. 2 is a flow diagram of an example method 200 for fabricating FET 100 with cross-sectional views shown in FIGS. 1B and 1C, according to some embodiments. For illustrative purposes, the operations illustrated in FIG. 2 will be described with reference to the example fabrication process for fabricating FET 100 as illustrated in FIGS. 3-15. FIGS. 3-15 are cross-sectional views of FET 100 along line A-A of FIG. 1A at various stages of its fabrication, according to some embodiments. Operations can be performed in a different order or not performed depending on specific applications. It should be noted that method 200 may not produce a complete FET 100. Accordingly, it is understood that additional processes can be provided before, during, and after method 200, and that some other processes may only be briefly described herein. Elements in FIGS. 3-15 with the same annotations as elements in FIGS. 1A-1C are described above.

In operation 205, a superlattice structure is formed on a fin base on a substrate, and polysilicon structures are formed on the superlattice structure. For example, as shown in FIG. 3, fin base 106 is formed on substrate 104, superlattice structure 307 is formed on fin base 106, and polysilicon structures 318 are formed on superlattice structure 307. In some embodiments, oxide layers 342 and nitride layers 344 can be formed during the formation of polysilicon structures 318. Superlattice structure 307 can include nanostructured layers 116 and 316 arranged in an alternating configuration. In some embodiments, nanostructured layers 116 and 316 include materials different from each other. In some embodiments, nanostructured layers 116 can include Si and nanostructured layers 316 can include SiGe. Nanostructured layers 316 are also referred to as sacrificial layers 316. During subsequent processing, polysilicon structures 318, oxide layers 342, nitride layers 344, and sacrificial layers 316 can be replaced with gate structures 118 in a gate replacement process. In some embodiments, outer gate spacers 124 can be formed after the formation of polysilicon structures 318.

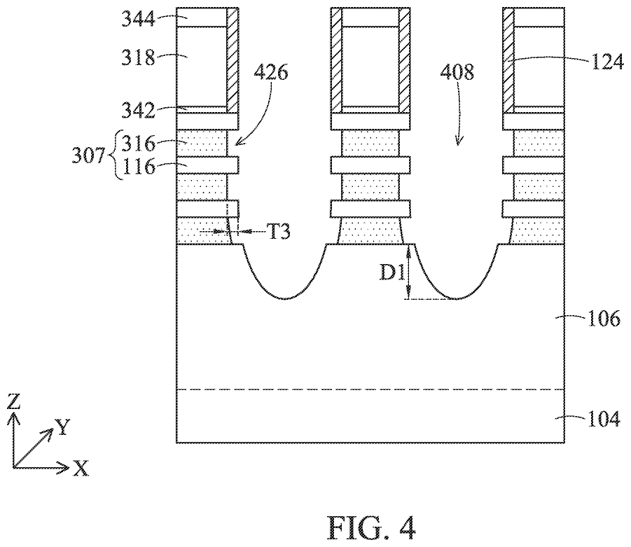

Referring to FIG. 2, in operation 210, S/D openings are formed on the fin base and spacer openings are formed in the superlattice structure. For example, as shown in FIG. 4, S/D openings 408 are formed on fin base 106 and spacer openings 426 are formed on superlattice structure 307. S/D openings 408 can be formed by etching the portions of superlattice structure 307 not covered by polysilicon structures 318. In some embodiments, S/D openings 408 extend distance D1 into fin base 106 to ensure complete removal of the portions of sacrificial layers 316 disposed directly on fin base 106 in S/D openings 408. In some embodiments, the etching of superlattice structure 307 and fin base 106 can include a plasma-based dry etching process using etching gases, such as carbon tetrafluoride (CF₄), sulfur dioxide (SO₂), hexafluoroethane (C₂F₆), chlorine (Cl₂), nitrogen trifluoride (NF₃), sulfur hexafluoride (SF₆), and hydrogen bromide (HBr), with mixture gases, such as hydrogen (H₂), oxygen (O₂), nitrogen (N₂), and argon (Ar). The etching can be performed at a temperature ranging from about 25° C. to about 200° C. under a pressure from about 5 mTorr to about 50 mTorr. The flow rate of the etching gases can range from about 5 standard cubic centimeters per minute (sccm) to about 100 sccm. The plasma power can range from about 50 W to about 200 W with a bias voltage from about 30 V to about 200 V.

The formation of S/D openings 408 can be followed by the formation of spacer openings 426 by performing an etching process on sidewalls of sacrificial layers 316 facing S/D openings 408. The etching process can laterally etch sacrificial layers 316 to laterally recess the sidewalls of sacrificial layers 316 by thickness T3 with respect to sidewalls of nanostructured layers 116 facing S/D openings 408. The etching process can include a dry etching process that has a higher etch selectivity for SiGe of sacrificial layers 316 than Si of nanostructured layers 116. For example, halogen-based chemistries can exhibit etch selectivity that is higher for Ge than for Si. Therefore, halogen gases can etch SiGe faster than Si. In some embodiments, the halogen-based chemistries can include fluorine-based and/or chlorine-based gasses. Alternatively, the etching of sacrificial layers 316 can include a wet etching process with a higher selectivity for SiGe than Si. For example, the wet etching process can include using a mixture of sulfuric acid (H₂SO₄) and hydrogen peroxide (H₂O₂) and/or a mixture of ammonia hydroxide (NH₄OH) with H₂O₂ and deionized (DI) water.

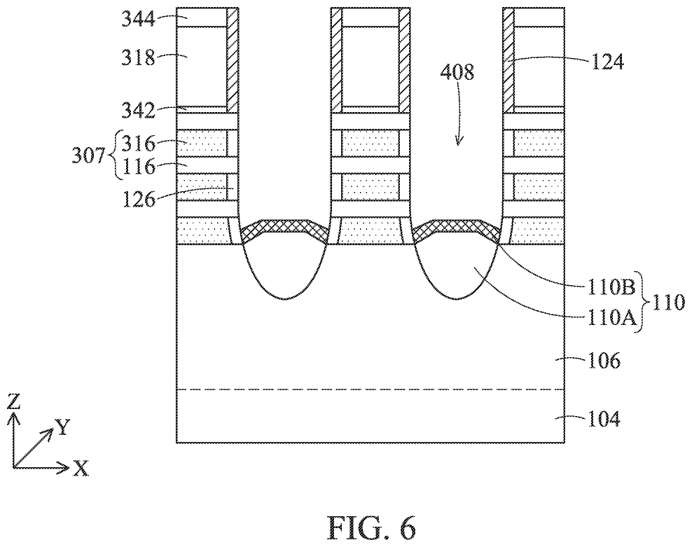

Referring to FIG. 2, in operation 215, EGI layers are formed in the S/D openings and inner gate spacers are formed in the spacer openings. For example, as described with reference to FIGS. 5 and 6, EGI layers 110 are formed in S/D openings 408 and inner gate spacers 126 are formed in spacer openings 426. In some embodiments, first dielectric layers 110A of EGI layers 110 can be formed along with inner gate spacers 126, as shown in FIG. 5. In some embodiments, first dielectric layers 110A and inner gate spacers 126 can be formed from the same dielectric material layer. The formation of first dielectric layers 110A and inner gate spacers 126 can include sequential operations of (i) depositing a first dielectric material layer (not shown) on the structure of FIG. 4 to fill S/D openings 408 and spacer openings 426, and (ii) etching the first dielectric material layer to form the structure of FIG. 5. In some embodiments, the etching of the first dielectric material layer can be an anisotropic dry etching process and can have a higher etching rate along a Z-axis rather than along an X-axis or a Y-axis. As a result, the portions of the first dielectric material layer in S/D openings 408 can be etched to form first dielectric layers 110A without etching the portions of the dielectric material layer in spacer openings 426.

The formation of first dielectric layers 110A and inner gate spacers 126 can be followed by the formation of second dielectric layers 110B of EGI layers 110. The formation of second dielectric layers 110B can include sequential operations of (i) depositing a second dielectric material layer (not shown) on the structure of FIG. 5 to fill S/D openings 408, and (ii) etching the second dielectric material layer to form the structure of FIG. 6. In some embodiments, the etching of the second dielectric material layer can be an anisotropic dry etching process and can have a higher etching rate along a Z-axis rather than along an X-axis or a Y-axis. As a result, the second dielectric material layer in S/D openings 408 can be etched to form second dielectric layers 110B without substantial etching of inner gate spacers 126.

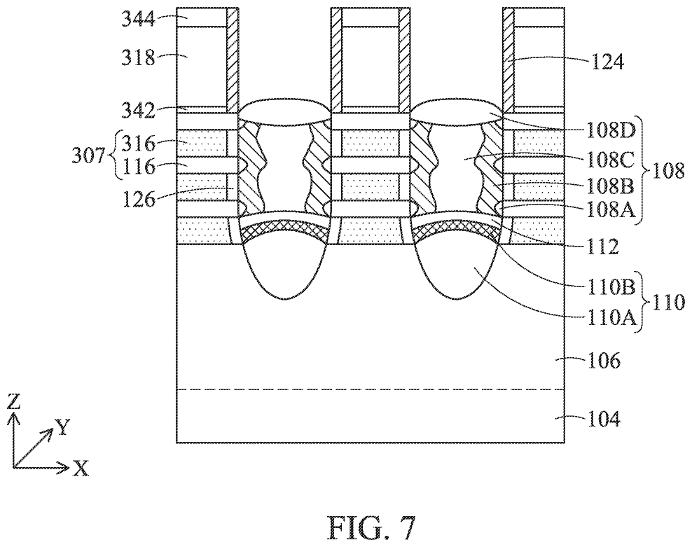

Referring to FIG. 2, in operation 220, S/D regions are formed in the S/D openings. For example, as shown in FIG. 7, S/D regions 108 are formed in S/D openings 408. The formation of S/D regions 108 can include sequential operations of (i) epitaxially growing S/D sub-regions 108A on sidewalls of nanostructured layers 116 facing S/D openings 408, as shown in FIG. 7, (ii) epitaxially growing a pair of S/D sub-regions 108B on S/D sub-regions 108A in each S/D opening 408, as shown in FIG. 7, (iii) epitaxially growing S/D sub-regions 108C on S/D sub-regions 108B, as shown in FIG. 7, and (iv) epitaxially growing S/D sub-regions 108D on S/D sub-regions 108A, 108B, and 108C, as shown in FIG. 7. In some embodiments, the epitaxial growth of each S/D sub-region 108B on S/D sub-regions 108A can start by growing epitaxial layers directly on each S/D sub-region 108A. The epitaxial growth of each S/D sub-region 108B can be continued until the epitaxial layers on adjacent S/D sub-regions 108A vertically extend to merge with each other and form a continuous epitaxial layer of S/D sub-region 108B along a sidewall of S/D opening 408. The merged portions of S/D sub-regions 108B can be formed on sidewalls of inner gate spacers 126, as shown in FIG. 7.

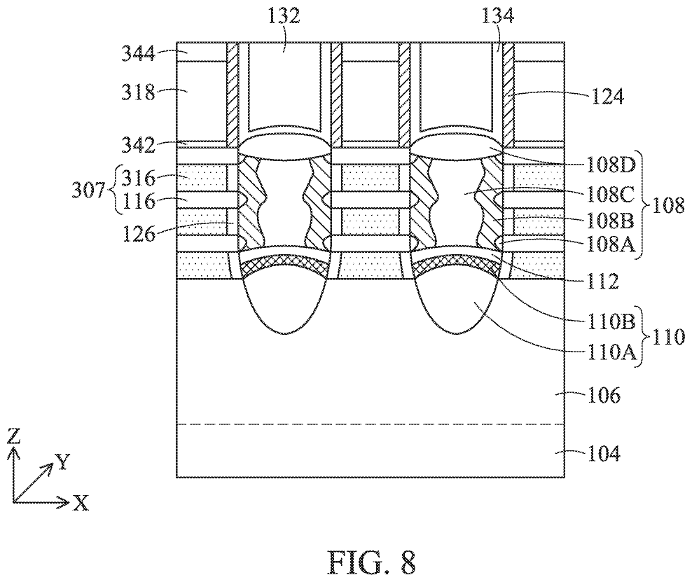

In some embodiments, the formation of S/D regions 108 can be followed by the formation of ILD layers 132 and ESLs 134, as shown in FIG. 8.

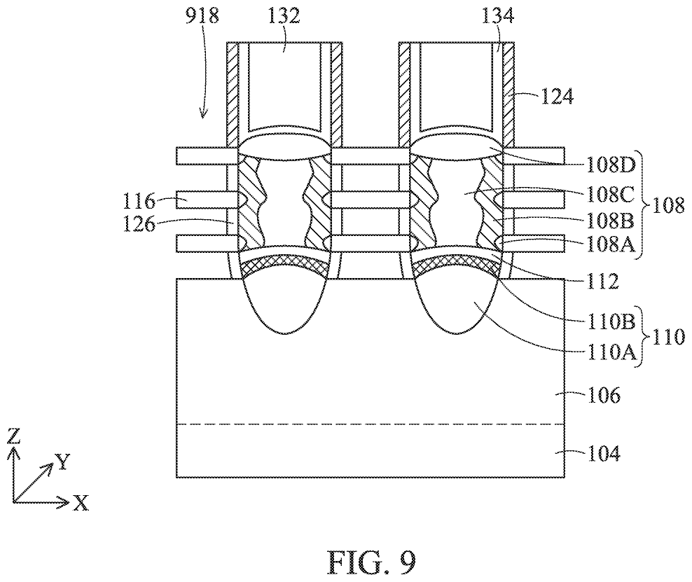

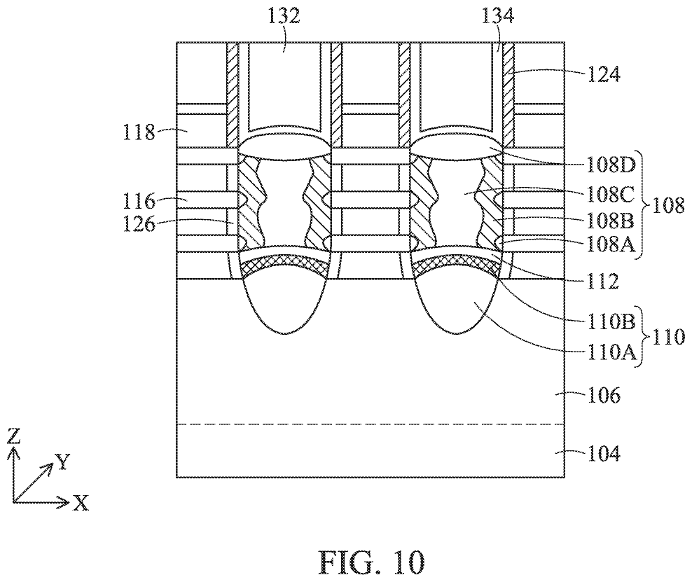

Referring to FIG. 2, in operation 225, the polysilicon structures and sacrificial layers of the superlattice structure are replaced with gate structures. For example, as described with reference to FIGS. 9 and 10, polysilicon structures 318 and sacrificial layers 316 are replaced with gate structures 118. The formation of gate structures 118 can include removing nitride layers 344, polysilicon structures 318, oxide layers 342, and sacrificial layers 316 from the structure of FIG. 8 to form gate openings 918, as shown in FIG. 9, and forming gate structures gate openings 918, as shown in FIG. 10. In some embodiments, the formation of gate structures 118 can be followed by the formation of conductive capping layers 120 and insulating capping layers 122, as shown in FIG. 10.

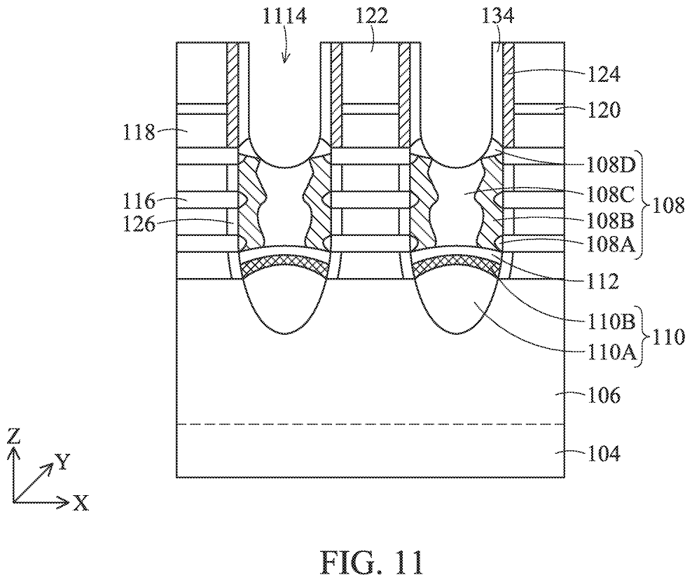

Referring to FIG. 2, in operation 230, first S/D contact structures are formed on front-sides of the S/D regions. For example, as described with reference to FIGS. 11 and 12, S/D contact structures 114 are formed on front-sides of S/D regions 108. The formation of S/D contact structures 114 can include sequential operations of (i) forming contact openings 1114 by etching ILD layers 132 from top surfaces of S/D sub-regions 108D and etching portions of S/D sub-regions 108D from top surfaces of S/D sub-regions 108B and 108C, as shown in FIG. 11, (ii) forming silicide layers 114A on the exposed surfaces of S/D sub-regions 108B, 108C, and 108D in contact openings 1114, as shown in FIG. 12, (iii) depositing a conductive layer (not shown) on silicide layers 114A to fill contact openings 1114, and (iv) performing a chemical mechanical polishing (CMP) process to substantially coplanarize top surfaces of the conductive layer and insulating capping layers 122, as shown in FIG. 12. In some embodiments, S/D contact structures 114 can be misaligned with S/D regions 108 along an X-axis by about 2.5 nm to about 3 nm. In some embodiments, the formation of S/D contact structures 114 can be followed by the formation of gate contact structures 128, as shown in FIG. 12. In some embodiments, gate contact structures 128 can be misaligned with gate structures 118 along an X-axis by about 2.5 nm to about 3.5 nm.

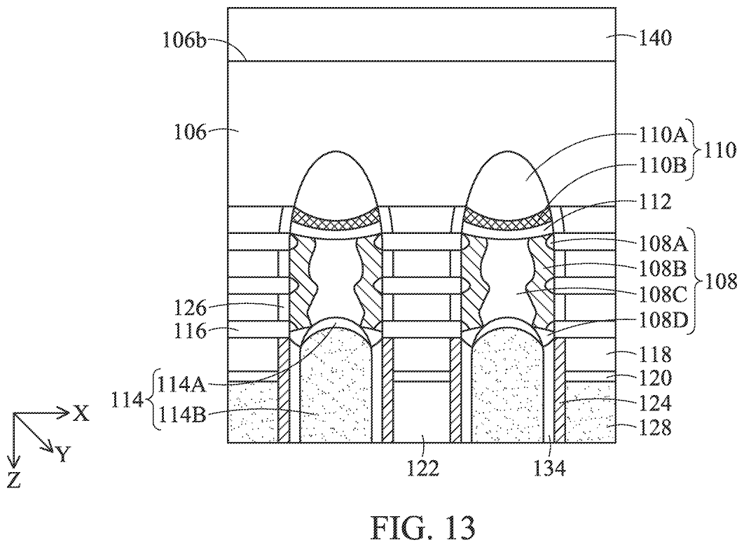

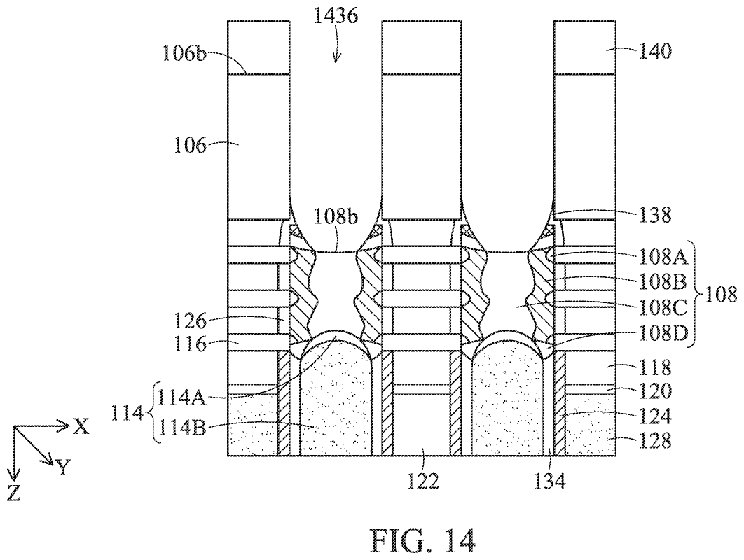

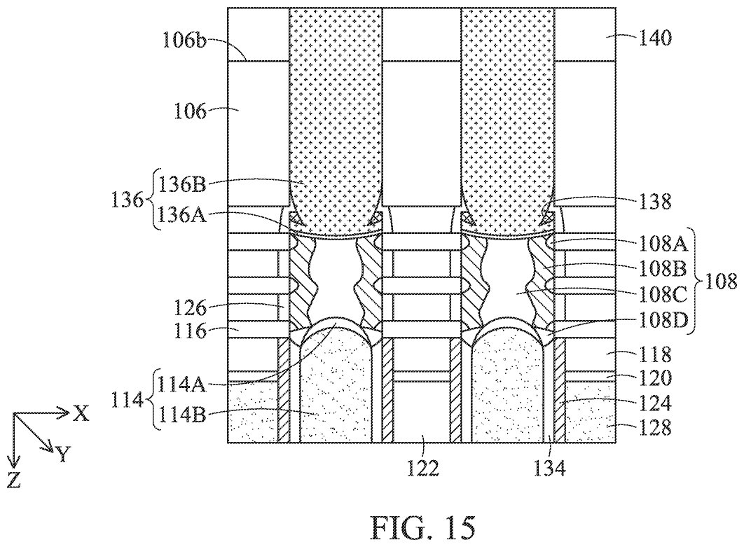

Referring to FIG. 2, in operation 235, second S/D contact structures are formed on back-sides of the S/D regions. For example, as described with reference to FIGS. 13, 14, and 15, back-side S/D contact structures 136 are formed on back-sides 108b of S/D regions 108. The formation of back-side S/D contact structure 136 can include sequential operations of (i) removing substrate 104, as shown in FIG. 13, (ii) depositing back-side dielectric layer 140 on back-side 106b of fin base 106, as shown in FIG. 13, (iii) forming contact openings 1436 on back-sides 108b of S/D regions 108, as shown in FIG. 14, 1746, (iv) forming silicide layers 136A on the exposed back-sides 108b in contact openings 1436, as shown in FIG. 15, (v) depositing a layer (not shown) having the material of contact plugs 136B, and (vi) performing a CMP process on the layer to form contact plugs 136B, as shown in FIG. 15.

In some embodiments, contact openings 1436 can be formed by using a photolithographic patterning process and an etching process to remove portions of back-side dielectric layer 140, fin base 106, and EGI layers 110 under S/D regions 108. In some embodiments, the etching process can include a dry etching process using etchants including chlorine (Cl₂), hydrogen bromide (HBr), and oxygen (O₂). In some embodiments, anchor structures 138 can be formed during the etching of EGI layers 110. In some embodiments, back-side S/D contact structures 136 can be misaligned with S/D regions 108 along an X-axis by about 3 nm to about 4.5 nm.

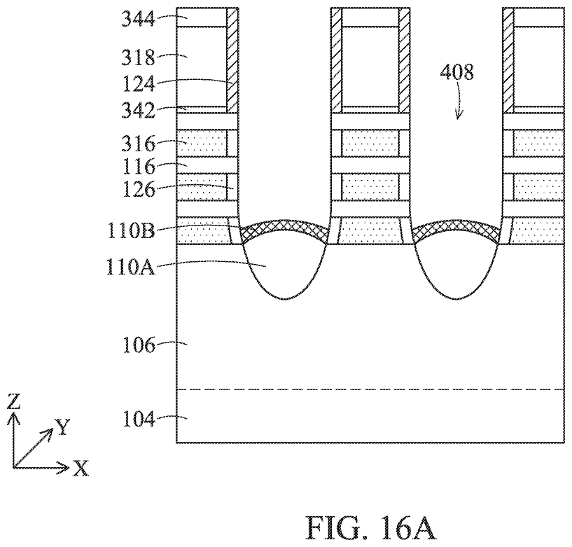

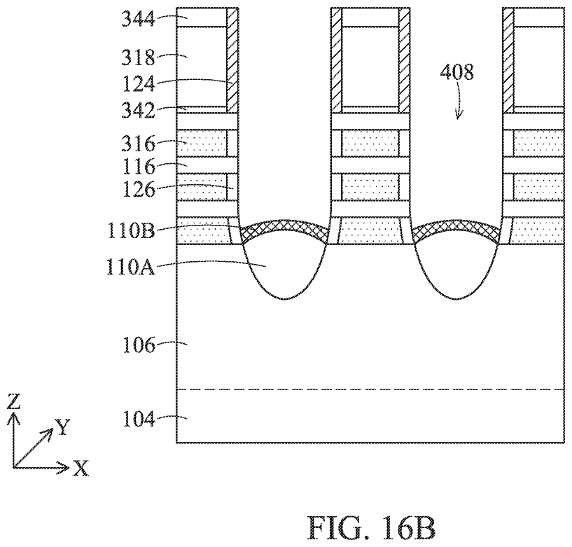

In some embodiments, method 200 of FIG. 2 can be used to form NFET 100 and PFET 100 substantially parallel to each other on same substrate 104. In some embodiments, the elements of NFET 100 and PFET 100 can be formed at the same time, except for their S/D regions, which can be formed sequentially. FIGS. 16A-19B illustrate the sequential formation of S/D regions 108N of NFET 100 and S/D regions 108P of PFET 100. The discussion of S/D regions 108 applies to S/D regions 108N and 108P, unless mentioned otherwise. FIGS. 16A-19A show cross-sectional views of NFET 100 and FIGS. 16B-19B show cross-sectional views of PFET 100 at various stages of their fabrication, according to some embodiments. Elements in FIGS. 16A-19B with the same annotations as elements in FIGS. 1A-1C and 3-15 are described above.

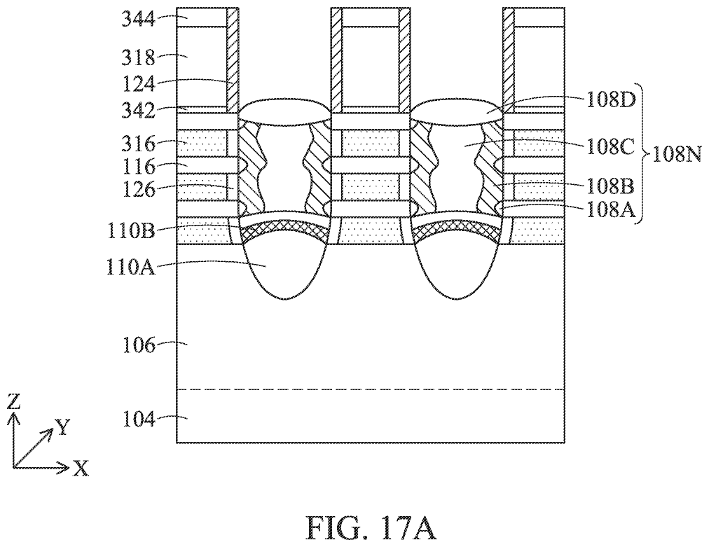

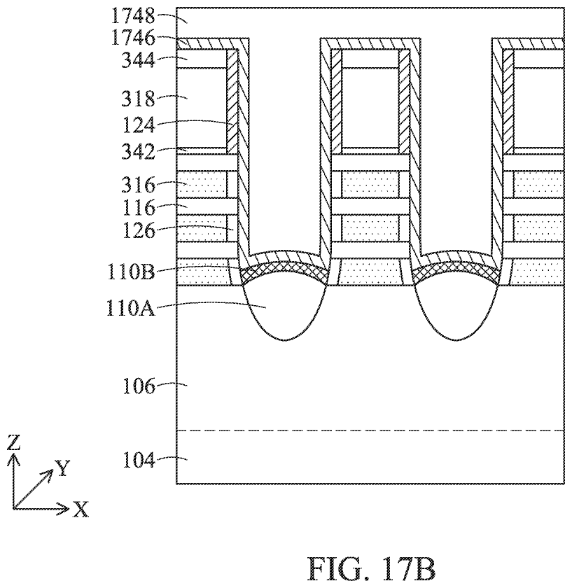

Prior to the formation of S/D regions 108N and 108P, the structures of FIGS. 16A and 16B can be formed by performing operations 205, 210, and 215 of FIG. 2 on substrate 104. Fin bases 106 of NFET 100 and PFET 100 can be substantially parallel to each other. In some embodiments, the formation of S/D regions 108N can be followed by the formation of S/D regions 108P. The formation of S/D regions 108N can include sequential operations of (i) depositing a bottom anti-reflective coating (BARC) layer 1746 on the structure of PFET 100 in FIG. 16B to form the structure of FIG. 17B, (ii) depositing a hard mask layer 1748 (e.g., aluminum oxide (AlOₓ) layer) on BARC layer 1746, (iii) performing operation 220 of FIG. 2 on the structure of NFET 100 in FIG. 16A to form S/D regions 108N, as shown in FIG. 17A, and (iv) removing hard mask layer 1748 and BARC layer 1746 from the structure of FIG. 17B.

BARC layer 1746 and hard mask layer 1748 can prevent S/D regions 108N from being formed in S/D openings 408 of PFET 100. In some embodiments, operation 220 can form S/D regions 108N with S/D sub-regions 108A, 108B, 108C, and 108D having epitaxially-grown Si without any Ge atoms. In some embodiments, S/D sub-regions 108A can be formed without any dopants. In some embodiments, S/D sub-regions 108B can be formed with an arsenic dopant concentration of about 1×10²⁰ atoms/cm³ to about 1×10²¹ atoms/cm³. In some embodiments, S/D sub-regions 108C can be formed with a phosphorus dopant concentration of about 1×10²¹ atoms/cm³ to about 4×10²¹ atoms/cm³. In some embodiments, S/D sub-regions 108D can be formed with a phosphorus dopant concentration of about 1×10²¹ atoms/cm³ to about 2×10²¹ atoms/cm³.

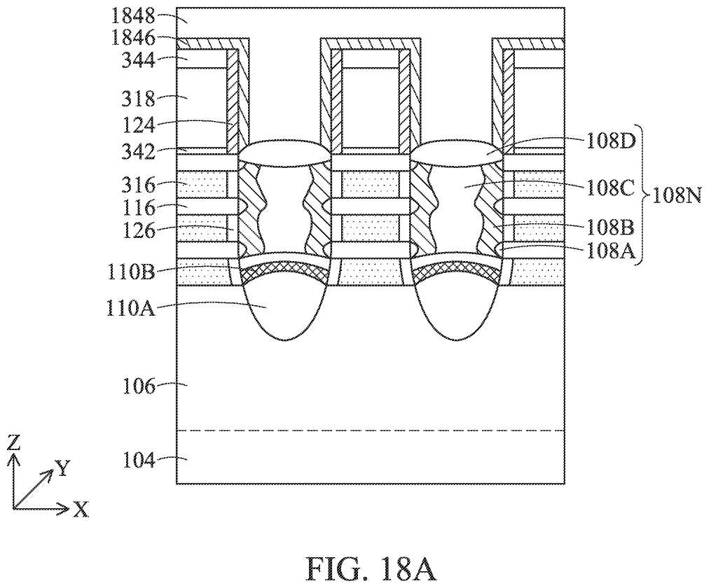

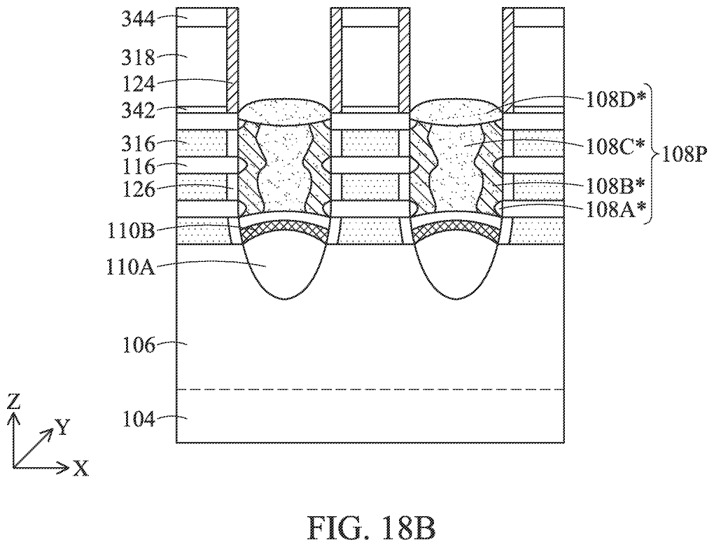

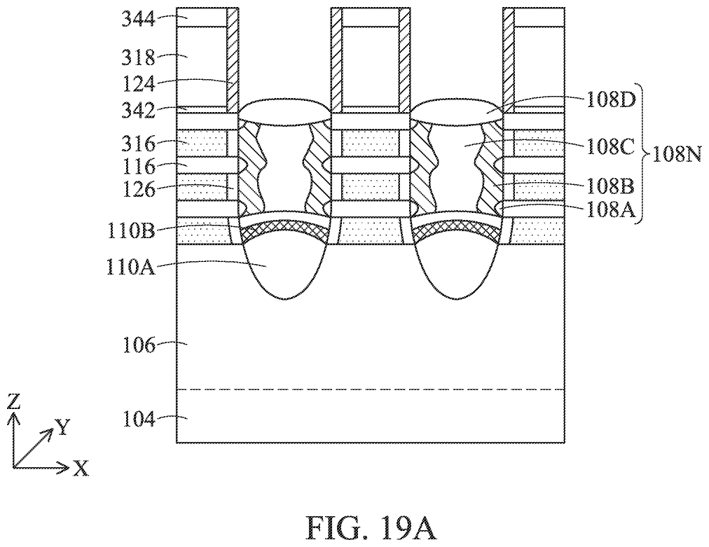

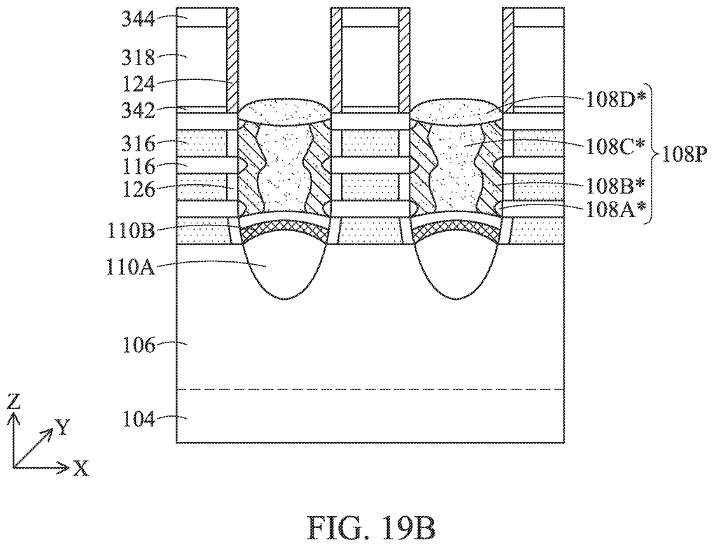

Similar to the formation of S/D regions 108N, the formation of S/D regions 108P can include sequential operations of (i) depositing a BARC layer 1846 on the structure of NFET 100 in FIG. 17A to form the structure of FIG. 18A, (ii) depositing a hard mask layer 1848 (e.g., AlOₓ layer) on BARC layer 1846, (iii) performing operation 220 of FIG. 2 on the structure of PFET 100 after removing hard mask layer 1748 and BARC layer 1746 to form S/D regions 108P, as shown in FIG. 18B, and (iv) removing hard mask layer 1848 and BARC layer 1846 from the structure of FIG. 18A to form the structure of FIG. 19A.

BARC layer 1846 and hard mask layer 1848 can prevent S/D regions 108P from being formed on S/D regions 108N. In some embodiments, operation 220 can form S/D regions 108P with S/D sub-regions 108A* having epitaxially-grown Si without any Ge atoms and S/D sub-regions 108B*, 108C*, and 108D* having epitaxially-grown SiGe. In some embodiments, S/D sub-regions 108A* can be formed without any dopants. In some embodiments, S/D sub-regions 108B* can be formed with a Ge atom concentration of about 25 atomic % to about 45 atomic % and a boron dopant concentration of about 1×10²⁰ to about 8×10²⁰ atoms/cm³. In some embodiments, S/D sub-regions 108C* can be formed with a Ge atom concentration of about 45 atomic % to about 60 atomic % and a boron dopant concentration of about 8×10²⁰ atoms/cm³ to about 3×10²¹ atoms/cm³. In some embodiments, S/D sub-region 108D* can be formed with a Ge atom concentration of about 45 atomic % to about 55 atomic % and a boron dopant concentration of about 1×10²¹ atoms/cm³ to about 2×10²¹ atoms/cm³.

In some embodiments, operations 225, 230, and 235 can be performed on the structures of FIGS. 19A and 19B to form S/D contact structures 114 and 136 and gate structures 128 in NFET 100 and PFET 100.

The present disclosure provides examples methods (e.g., method 200) of forming epitaxial S/D regions (e.g., S/D regions 108) on nanostructured channel regions (e.g., nanostructured channel regions 116) that can prevent or mitigate the formation of voids and/or crystal defects in the S/D regions. In some embodiments, air spacers (e.g., air spacers 112) and dielectric layers (e.g., EGI layers 110) can be formed between S/D regions and fin bases (e.g., fin base 106) to limit the epitaxial growth of the S/D regions to the sidewalls of the nanostructured channel regions and to prevent any epitaxial growth of the S/D regions on the fin bases. As a result, the merging of different epitaxial portions grown on different surfaces can be prevented, which can prevent or mitigate the formation of voids and/or crystal defects in the S/D regions.

In some embodiments, portions of the fin bases under the dielectric layers can be replaced with back-side contact structures (e.g., back-side S/D contact structures 136) and the dielectric layers can be etched to form anchor structures (e.g., anchor structures 138) to prevent the metal of the back-side contact structures from being pulled out during a planarization operation. The back-side contact structures can be electrically connected to a back-side power rail formed in a back-side dielectric layer disposed on a back-side of the substrate. In some embodiments, the formation of the back-side power rail and the electrical connections of one or more of the S/D regions to the back-side power rail can reduce device area and the number and dimension of interconnects between S/D regions and power rails, thus reducing device power consumption compared to other semiconductor devices without back-side power rails.

In some embodiments, a semiconductor device includes a substrate, a fin base disposed on the substrate, nanostructured channel regions disposed on a first portion of the fin base, a gate structure surrounding the nanostructured channel regions, a S/D region disposed on a second portion of the fin base, an air spacer disposed between the S/D region and the fin base, and a dielectric layer disposed between the air spacer and the fin base.

In some embodiments, a semiconductor device includes a fin base, nanostructured channel regions disposed on a first portion of the fin base, a gate structure surrounding the nanostructured channel regions, a S/D region disposed on a second portion of the fin base, a first contact structure disposed on a first surface of the S/D region, a second contact structure disposed on a second surface of the S/D region and in the fin base, and an anchor structure disposed between the fin base and the second contact structure.

In some embodiments, a method includes forming a fin base on a substrate, forming a stack of first and second nanostructured layers in an alternating configuration on the fin base, forming a polysilicon structure on a first portion of the stack first and second nanostructured layers, forming a first opening extending through a second portion of the stack first and second nanostructured layers into a portion of the fin base uncovered by the polysilicon structure, forming second openings in the first portion of the stack first and second nanostructured layers, depositing a dielectric layer to fill the first and second openings, removing a portion of the dielectric layer in the first opening to expose sidewalls of the first nanostructured layers, and forming a S/D region on the sidewalls of the first nanostructured layers in the first opening.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a fin base disposed on the substrate;
nanostructured channel regions disposed on a first portion of the fin base;
a gate structure surrounding the nanostructured channel regions;
a source/drain (S/D) region disposed on a second portion of the fin base;
an air spacer disposed between the S/D region and the fin base; and
a dielectric layer disposed between the air spacer and the fin base.

2. The semiconductor device of claim 1, wherein a first portion of the dielectric layer extends into the fin base and a second portion of the dielectric layer extends above a top surface of the fin base.

3. The semiconductor device of claim 1, wherein the dielectric layer comprises:
a first nitride layer disposed in the fin base; and
a second nitride layer disposed on the first nitride layer and above a top surface of the fin base.

4. The semiconductor device of claim 1, wherein the S/D region comprises S/D sub-regions disposed on sidewalls of the nanostructured channel regions and non-overlapping with each other.

5. The semiconductor device of claim 1, wherein the S/D region comprises:
a doped S/D sub-region extending along a sidewall of the S/D region; and
undoped S/D sub-regions disposed on sidewalls of the nanostructured channel regions, wherein the undoped S/D sub-regions are separated from each other by the doped S/D sub-region.

6. The semiconductor device of claim 1, wherein the S/D region comprises:
a first S/D sub-region disposed directly on the air spacer; and
second and third S/D sub-regions disposed directly on the air spacer and along opposite sidewalls of the first S/D sub-region.

7. The semiconductor device of claim 1, wherein the S/D region comprises:
first S/D sub-regions with triangular-shaped cross-sectional profiles disposed on sidewalls of the nanostructured channel regions;
a pair of second S/D sub-regions disposed on the first S/D sub-regions, wherein sidewalls of the pair of second S/D sub-regions facing each other comprise zig-zag-shaped cross-sectional profiles; and
a third S/D sub-region disposed between the pair of second S/D sub-regions.

8. The semiconductor device of claim 1, further comprising:
a first spacer disposed between a first portion of the gate structure and the S/D region; and
a second spacer disposed directly on the fin base and between a second portion of the gate structure and the air spacer.

9. The semiconductor device of claim 1, further comprising a spacer disposed directly on the fin base and between the gate structure and the dielectric layer, wherein the spacer and the dielectric layer comprise a same nitride material.

10. The semiconductor device of claim 1, further comprising spacers disposed between the gate structure and the S/D region, wherein the S/D region comprises:
first S/D sub-regions disposed on sidewalls of the nanostructured channel regions, and
a second S/D sub-region comprising first portions disposed on the first S/D sub-regions and second portions disposed on sidewalls of the spacers.

11. A semiconductor device, comprising:
a fin base;
nanostructured channel regions disposed on a first portion of the fin base;
a gate structure surrounding the nanostructured channel regions;
a source/drain (S/D) region disposed on a second portion of the fin base;
a first contact structure disposed on a first surface of the S/D region;
a second contact structure disposed on a second surface of the S/D region and in the fin base; and
an anchor structure disposed between the fin base and the second contact structure.

12. The semiconductor device of claim 11, wherein a first portion of the second contact structure is disposed between the anchor structure and the S/D region, and wherein a second portion of the second contact structure is disposed below the anchor structure.

13. The semiconductor device of claim 11, wherein the anchor structure comprises a triangular-shaped cross-sectional profile with first and second sides disposed in the second contact structure and a third side disposed on a sidewall of the fin base facing the second contact structure.

14. The semiconductor device of claim 11, wherein the anchor structure extends a distance of about 2 nm to about 15 nm from a sidewall of the fin base into the second contact structure.

15. The semiconductor device of claim 11, further comprising:
a first spacer disposed between a first portion of the gate structure and the S/D region; and
a second spacer disposed directly on the fin base and between a second portion of the gate structure and the second contact structure.

16. The semiconductor device of claim 11, further comprising a nitride layer disposed on a back surface of the fin base.

17. A method, comprising:
forming a fin base on a substrate;
forming a stack of first and second nanostructured layers in an alternating configuration on the fin base;
forming a polysilicon structure on a first portion of the stack of first and second nanostructured layers;
forming a first opening extending through a second portion of the stack of first and second nanostructured layers into a portion of the fin base uncovered by the polysilicon structure;
forming second openings in the first portion of the stack of first and second nanostructured layers;
depositing a dielectric layer to fill the first and second openings;
removing a portion of the dielectric layer in the first opening to expose sidewalls of the first nanostructured layers; and
forming a S/D region on the sidewalls of the first nanostructured layers in the first opening.

18. The method of claim 17, wherein forming the second openings comprises laterally etching the second nanostructured layers.

19. The method of claim 17, wherein forming the S/D region comprises epitaxially growing semiconductor layers with triangular-shaped cross-sectional profiles on sidewalls of the first nanostructured layers.

20. The method of claim 17, wherein removing the portion of the dielectric layer in the first opening comprises etching the dielectric layer with an etching rate that is higher in a vertical direction than in a lateral direction.
